(19) United States
(12) Patent Application Publication
(10) Pub. No.: US 2007/0048951 A1
(43) Pub. Date: Mar. 1, 2007

(54) Method for production of semiconductor memory devices

(76) Inventors: Hocine Boubekeur, Dresden (DE); Dominik Olligs, Dresden (DE); Torsten Mueller, Dresden (DE); Christoph Andreas Kleint, Dresden (DE); David Pritchard, Dresden (DE)

Correspondence Address: SLATER & MATSIL LLP, 17950 PRESTON ROAD, SUITE 1000, DALLAS, TX, 75252, US

(21) Appl. No.: 11/216,526

(22) Filed: Aug. 31, 2005

(51) Int. Cl. H01L 21/336

(52) U.S. Cl. 438/301; 438/586; 438/595; 438/478; 438/682

(57) ABSTRACT

Dielectric gratings are formed between the word line stacks. Spacers are applied to the sidewalls of the word line stacks and the dielectric gratings. In the openings between the spacers, silicon is epitaxially grown on the upper surfaces of source/drain regions, which are implanted self-aligned to the word line stacks. A silicide is formed on the grown silicon, and a metal layer is applied and structured to form local interconnects, which connect the source/drain regions to upper bit lines.

### TECHNICAL FIELD

This invention is related to a method for production of semiconductor memory devices that include bitline contacts to source/drain regions that are located between the wordlines.

### BACKGROUND

In PCT application WO 2004/053982, which is incorporated herein by reference, a memory cell array is described that includes word lines and bit lines that are arranged above a main surface of a semiconductor substrate. The direction of the channels of the transistor structures forming the memory cells is transverse to the direction of the word lines. The appertaining source/drain regions are electrically connected by local interconnects that are arranged in the gaps between neighboring word lines. The bit lines are connected to the local interconnects according to a pattern that is required by the memory array architecture.

Memory devices with charge-trapping layers, especially SONOS memory cells comprising oxide-nitride-oxide layer sequences as storage medium, are usually programmed by channel hot electron injection. U.S. Pat. Nos. 5,768,192 and 6,011,725, which are both incorporated herein by reference, disclose charge-trapping memory cells of a special type of so-called NROM cells, which can be used to store bits of information both at the source and at the drain below the respective gate edges. The programmed cell is read in reverse mode to achieve a sufficient two-bit separation. Erasure is performed by hot hole injection.

FIG. 1 shows a plan view of a scheme of a semiconductor memory according to the cited prior art, in which the channel regions are directed transversely with respect to the relevant word line and the bit lines are arranged on top of the word lines and electrically insulated from the word lines. Shallow trench isolations 1 represent a multiplicity of isolation trenches that are arranged parallel at a distance from one another and are filled with dielectric material, preferably with an oxide of the semiconductor material. The channel regions of the memory transistors run parallel to the isolation trenches underneath the word lines 2 and are arranged between two adjacent shallow trench isolations 1. Thus, the word lines are transverse to the longitudinal extension of the channel regions. Electrically conductive interconnects 6 are present in interspaces between the word lines 2 and are electrically insulated from the word lines by lateral word line insulations 3 and from one another by a dielectric material that is filled into the interspaces. The local interconnects are connected to the bit lines, which are arranged above the word lines and electrically insulated from the word lines.

The source/drain regions of the memory transistors are in each case present in a manner laterally adjoining the word lines. Neighboring source/drain regions are electrically conductively connected to one another in the regions that are highlighted by the hatchings in FIG. 1, a short section of one of the shallow trench isolations being bridged in each case.

In accordance with a consecutive numbering of the memory transistors along a respective word line, the interconnects 6 electrically conductively connect, on one side of the word line, in each case a source/drain region of an even-numbered memory transistor to a source/drain region of the subsequent odd-numbered memory transistor in the numbering and, on the opposite side of this word line, in each case a source/drain region of an odd-numbered memory transistor to a source/drain region of the subsequent even-numbered memory transistor in the numbering.

FIG. 2 illustrates a plan view of this arrangement including the bit lines 4 applied above the word lines parallel to the shallow trench isolations. The local interconnects 6 that are present in the regions that correspond to the hatched areas of FIG. 1 are each designated in FIG. 2 by one lower-case letter. The interconnects 6 are contact-connected by the bit lines 4. The bit line contacts 5 are depicted by broken lines as concealed contours in FIG. 2 and identified by a cross. Furthermore, the bit line contacts 5 are in each case designated by the upper-case letter that corresponds to the lower-case letter of the appertaining interconnect 6.

It can be seen in FIG. 2 that the bit lines 4 are in each case electrically contact-connected to interconnects 6 that are arranged successively in the direction of the bit lines in next but one interspaces between the word lines 2. The interconnects 6 bridge a shallow trench isolation 1 and each connect one source/drain region to a subsequent source/drain region of the same interspace between the adjacent word lines. They are electrically insulated from one another and, therefore, formed in sections and isolated from one another by dielectric material.

The local interconnects between the upper bitlines and the source/drain regions in the silicon substrate can be formed of metal. It is preferred to perform a salicidation process by which a metal silicide is produced in self-aligned fashion on the source/drain regions between the word line stacks. The metal silicide reduces the contact resistance between the local interconnects and the silicon of the substrate. As the pn-junctions of the source/drain regions are located in the immediate vicinity of the silicide contacts, a short-circuit of the junctions by silicide grains may occur. Therefore, the use of a salicidation process to improve the contact resistance becomes increasingly difficult for shallow junctions.

This problem can be avoided if first a silicon layer is applied on the upper surfaces of the source/drain regions. The silicon layer can be produced by a process in which crystalline silicon is grown epitaxially on the surface of the silicon substrate. In this way, the distance between the contact surface of the silicided metal and the junction can be increased so that there will no longer be any risk of silicide grains short-circuiting the junction. However, the epitaxial silicon growth necessitates pre-cleaning steps, which may attack the oxide of the shallow trench isolations. This will change the step height between the surfaces of the shallow trench isolations and the active areas, which is critical for the performance of the memory cells. If a dielectric material like BPSG (boron phosphorus silicate glass) is filled into the gaps between the word line stacks and via holes are formed in the dielectric material above the source/drain regions that are to be connected, difficulties arise from the extremely small lateral dimensions and the corresponding aspect ratio if the via holes are to be filled by an epitaxial silicon growth. The BPSG is prone to voids that may cause short-circuits of the contacts. Alternatively, epitaxial silicon may be filled before BPSG isolation with a subsequent inverse contact etch using photo resist posts over the contacts instead of via holes. However, the formation of posts of photo resist within the small interstices between the word line stacks is not possible in the desired dimensions.

### SUMMARY OF THE INVENTION

In one aspect, the present invention relates to a method for producing contacts to upper bitlines on source/drain regions that avoid the risk of short-circuiting the source/drain junctions.

In a further aspect, the invention relates to a method by which local interconnects can be formed that bridge the conducting material of each active source/drain over the dielectric material of the shallow trench isolations.

In still a further aspect, the invention relates to a method for producing the local interconnects in way that avoids short-circuits through the intermediate dielectric material that separates neighboring local interconnects.

The present invention also provides methods for producing semiconductor memory devices. According to one embodiment, a main surface of a silicon substrate is provided with shallow trench isolations running parallel at a distance from one another. A gate dielectric that includes a memory layer is formed on the main surface. At least one electrically conductive word line layer is formed on the gate dielectric. At least one electrically insulating material is formed above the word line layer(s). The electrically insulating material and the word line layer(s) are structured to form word line stacks running parallel at a distance from one another transversely to the shallow trench isolations and having sidewalls and gaps between them. Dopant atoms are implanted in a self-aligned manner with the word line stacks to form source/drain regions. A lateral word line insulation is formed on sidewalls of the word line stacks. A dielectric material is formed into the gaps between the word line stacks. A mask is formed with strip-like parts running above the shallow trench isolations and with openings or windows between the strips. The mask is used to remove the dielectric material in regions between the word line stacks and between the shallow trench isolations down to the surface of the substrate in areas of the source/drain regions, leaving residual parts of the dielectric material to form dielectric gratings between the word line stacks. Spacers of dielectric material are formed on sidewalls of the word line stacks and the dielectric gratings, leaving areas of the main surface above the source/drain regions free. A silicon layer is epitaxially grown on the main surface between the spacers. Contacts can then be provided for bitlines on the silicon layer.

Further process steps may comprise forming a silicide layer on the silicon layer; applying a metal layer on the silicide layer; structuring the metal layer to form local interconnects; applying bit lines running transversely to the word line stacks and being connected to the local interconnects.

The local interconnects formed in the metal layer can be arranged similarly to the prior art described above, as follows. The local interconnects are arranged between the word lines in such a fashion that in a first quadruple of memory cells comprising a first memory cell, a second memory cell that is adjacent to the first memory cell in a direction of the word lines, and a third memory cell and a fourth memory cell that are adjacent to the first and second memory cells, respectively, in a direction of the bit lines, and further comprising a first source/drain region of the first memory cell, a first source/drain region of the second memory cell, a first source/drain region of the third memory cell, and a first source/drain region of the fourth memory cell, the first source/drain regions are electrically connected by a first one of the local interconnects and, the memory cells of the first quadruple forming first memory cells of a second, third, fourth, and fifth quadruple of memory cells arranged like the first quadruple, a second source/drain region of each of the memory cells of the first quadruple is electrically connected to first source/drain regions of a second, third, and fourth memory cell of the respective second, third, fourth or fifth quadruple of memory cells by a second, third, fourth, and fifth one, respectively, of the local interconnects.

Advantages of this invention include the elimination of the difficult resist post mask for LOCHIS contact processing and the BPSG void shorts elimination with contact hole spacer that forms a well defined area of silicon in the contact hole for selective epi-silicon growth. The pre-clean for this step complicated the integration of this process to prior art NROM technologies, since the step height of the STI is critical for NROM performance. Furthermore, the raised silicon surface allows simplified integration of a salicide process to significantly reduce the contact resistance without shorting the shallow junction with salicide grain growth into the substrate. This disclosure enables the integration of the 70 nm process for NROM by removing these roadblocks.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross section of a plan view onto the memory device comprising local interconnects to upper bit lines;

FIG. 2 shows a plan view onto the device according to FIG. 1, including the arrangement of the bit lines;

FIG. 3 shows a cross section of a first intermediate product transversely to the direction of the word lines;

FIG. 4 shows a plan view according to FIGS. 1 and 2 after the application of a mask;

FIG. 5 shows the cross section according to FIG. 3, indicated in FIG. 4, of a further intermediate product after the formation of sidewall spacers;

FIG. 6 shows the cross section of the intermediate product of FIG. 5 between two neighboring word lines;

FIG. 7 shows the plan view according to FIG. 4 after the application of the sidewall spacers and the removal of the mask;

FIG. 8 shows the cross section according to FIG. 5 after an epitaxial growth process;

FIG. 9 shows the cross section according to FIG. 6 of the intermediate product according to FIG. 8;

FIG. 10 shows the cross section according to FIG. 8 after the application of local interconnects; and

FIG. 11 shows the cross section according to FIG. 9 after the application of local interconnects.

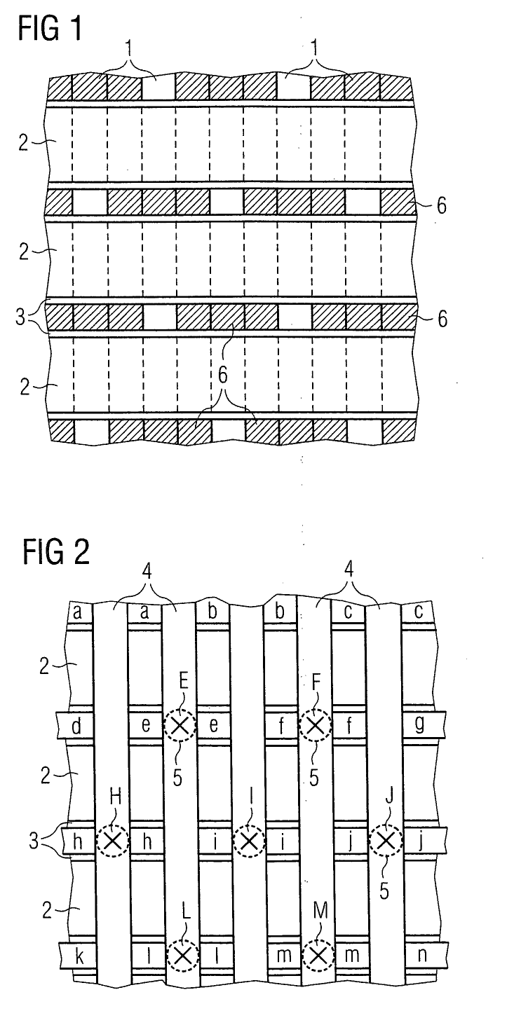

The following list of reference symbols can be used in conjunction with the figures: 1 shallow trench isolation 11 second word line layer 2 word line 12 top word line insulation 3 lateral word line insulation 13 dielectric material 4 bit line 14 mask 5 bit line contact 15 window 6 local interconnect 16 spacer 7 substrate 17 dielectric grating 8 source/drain region 18 silicon layer 9 gate dielectric 19 silicide layer 10 first word line layer 20 metal layer 11 second word line layer 12 top word line insulation 13 dielectric material 14 mask 15 window 16 spacer 17 dielectric grating 18 silicon layer 19 silicide layer 20 metal layer

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

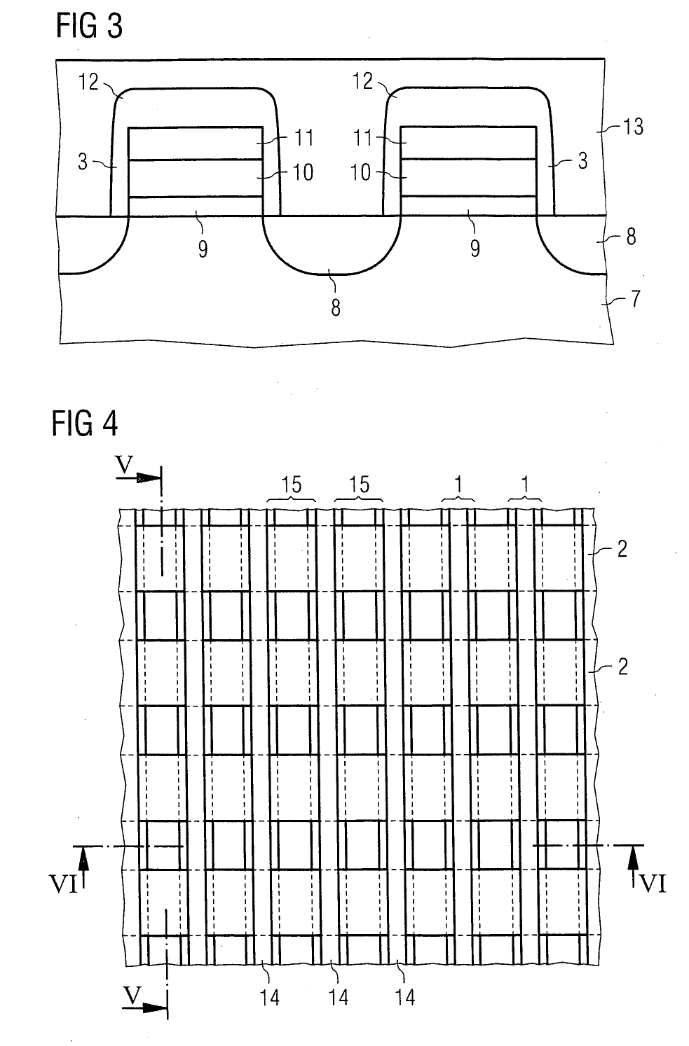

FIG. 3 shows a cross-sectional view perpendicular to the word line stacks of the memory device. In the silicon substrate 7 source/drain regions 8 are formed by an implantation of doping atoms, self-aligned to the word line stacks. The word line stacks comprise a gate dielectric 9, which can include a memory layer, especially a memory layer sequence formed of dielectric materials and being suitable for charge trapping. A first word line layer 10 is preferably formed of polysilicon, which is doped to be electrically conductive. A second word line layer 11 can be provided to reduce the track resistance. This second word line layer 11 can be a metal or metal silicide. A top word line insulation 12 can be formed of silicon nitride or another dielectric material. This material can especially be selected to be suitable as a hard mask, which is used in the formation of the word line stacks. The lateral word line insulation 3 is preferably applied in the form of sidewall spacers and may be used as a mask, if a second implantation of the source/drain regions is performed. The word line stacks and the intermediate gaps are filled and covered with a dielectric material 13. The dielectric material 13 can be, for example, boron phosphorus silicate glass (BPSG) or the deposit of a phosphorus high-density plasma (PHDP).

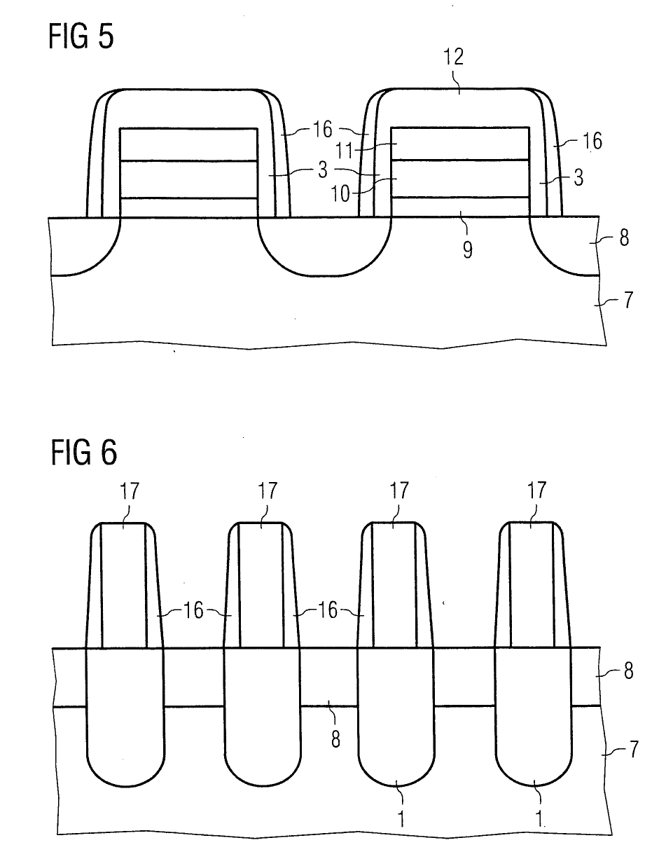

FIG. 4 shows a plan view on the upper structure of the intermediate product according to FIG. 3 after the application of a mask 14 and a subsequent etching step. The mask has windows 15 between striplike parts running above the shallow trench isolations 1. It is preferred if the windows 15 have lateral dimensions transversely to their striplike extension that are slightly larger than the lateral dimension of the active areas located between the shallow trench isolations 1. This means that marginal regions of the shallow trench isolations 1 are not covered by the strips of the mask 14. The cross sections that are indicated in FIG. 4 are shown in FIGS. 5 and 6.

FIG. 5 shows the cross section transversely to the word lines after the etching step, by which openings are etched into the dielectric material 13. In the example, which is shown in FIG. 5, the dielectric material 13 has completely been removed from the top word line insulation 12. Instead, the dielectric material 13 can be left on the top word line insulation 12 to reinforce the insulation. FIG. 5 shows the cross section in the area of the windows 15 of the mask 14, after the mask has been removed. Here, the dielectric material 13 is completely removed above the source/drain regions 8. In the openings between the word line stacks and the residual parts of the dielectric material, sidewall spacers 16 are formed of dielectric material by a conformal deposition of the spacer material and subsequent anisotropic etching.

FIG. 6 shows a cross section of the intermediate product according to FIG. 5 in a direction perpendicular to the cross section of FIG. 5 between two neighboring word line stacks. FIG. 6 shows the periodic succession of the shallow trench isolations 1, the source/drain regions 8 in between and the residual parts of the dielectric material, which now form a dielectric grating 17. The sidewalls of the dielectric grating 17 are also covered with the sidewall spacers 16. In the preferred variant of the method, the dielectric grating 17 does not cover the shallow trench isolations 1 completely, but the individual elements of the grating are slightly smaller than the shallow trench isolations. It is especially advantageous, if the spacer formation is performed in such a manner that the bottoms of the spacers have outer limits precisely at the boundary between the shallow trench isolations 1 and the source/drain regions 8 in the active areas. This arrangement is preferred, but usual process tolerances are allowed. It is in any case preferable to have the shallow trench isolations 1 completely covered by the dielectric grating 17 including the spacers 16. The spacers 16 are preferably nitride. The spacers 16 ensure that any voids in the material of the dielectric gratings 17 are covered and closed so that no short-circuit between the adjacent local interconnects will occur.

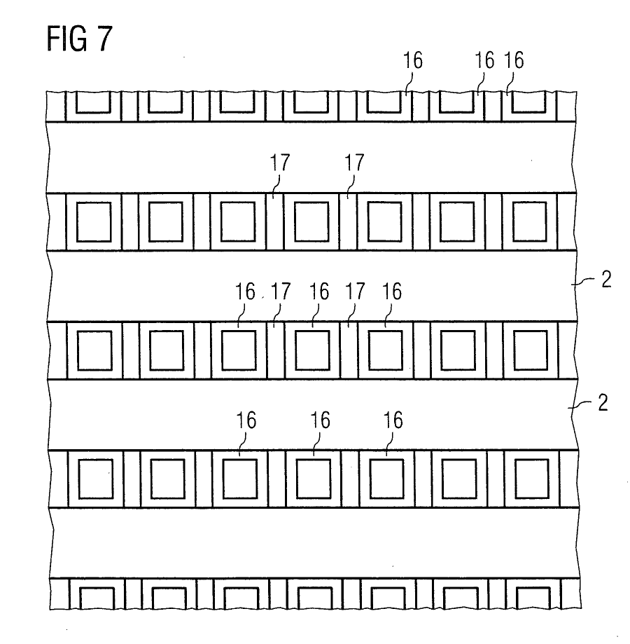

FIG. 7 shows the plan view according to FIG. 4 after the formation of the spacers 16. FIG. 7 clearly shows that the spacers cover the sidewalls of the openings between neighboring word lines 2 and the elements of the dielectric gratings 17.

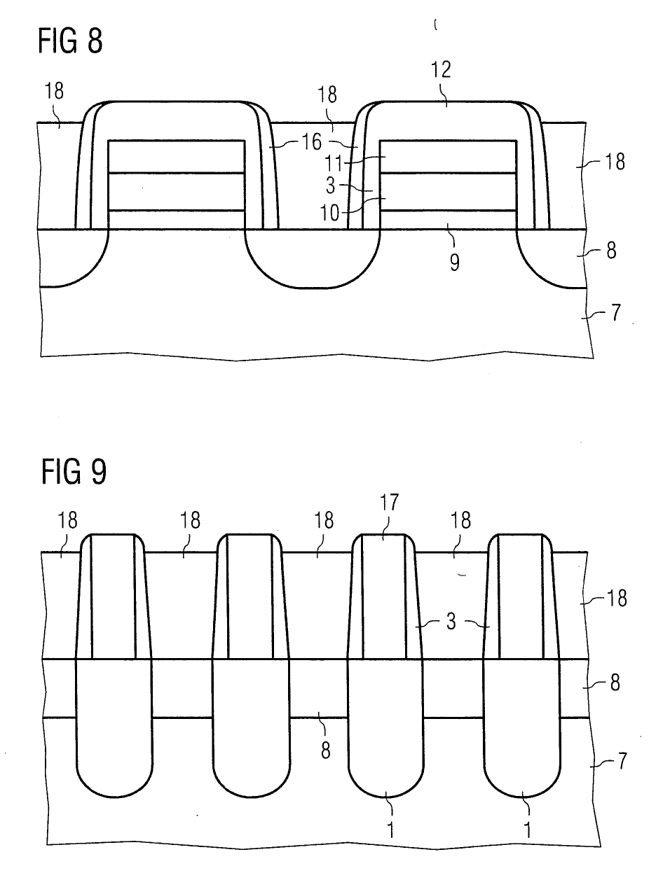

FIG. 8 shows the cross section according to FIG. 5 after an epitaxial growth of the silicon layer 18 on the free upper surfaces of the source/drain regions 8 in the openings between the word line stacks and the dielectric gratings 17. Preferably, the silicon layer 18 is grown to a level just below the upper edges of the top word line insulation 12.

FIG. 9 is the cross section according to FIG. 6 of the intermediate product of FIG. 8, which shows that the silicon layer 18 comprises independent parts that are separated and electrically insulated from one another by the dielectric gratings 17.

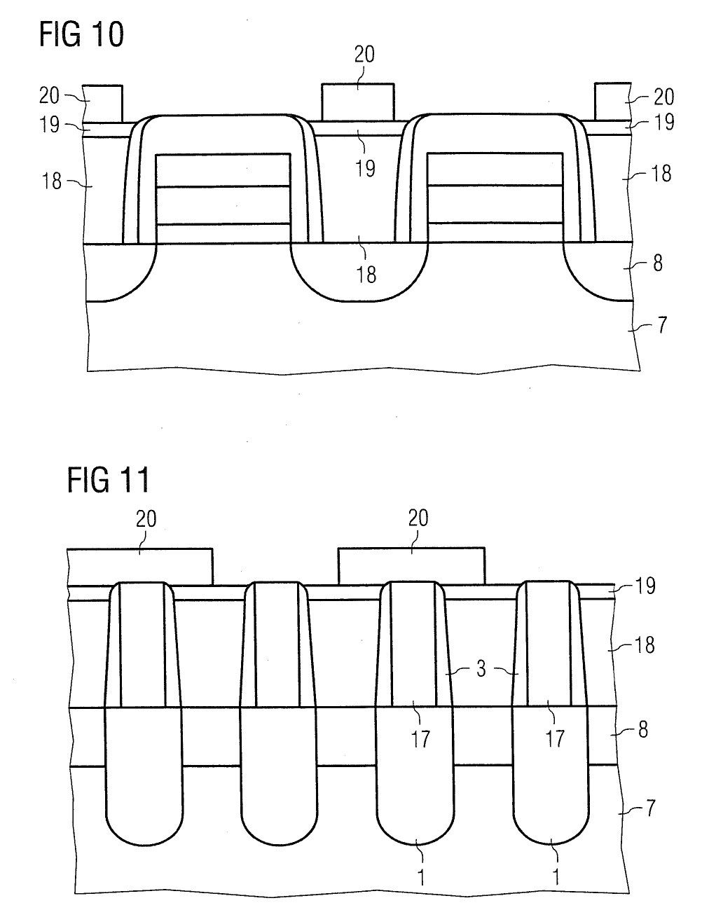

As shown in the cross section of FIG. 10, a contact conductor material, preferably a metal like Ti, Co or Ni, is applied on the upper surfaces of the silicon layer 18 to form a metal silicide by a salicide (self-aligned silicide) process. The silicide layer 19 comprises separate parts on the separate parts of the silicon layer 18 so that the electric connections to the source/drain regions 8 are still electrically insulated from one another. A metal layer 20 can then be applied and structured to form the local interconnects on which the upper bit lines are contacted.

FIG. 11 shows the cross section according to FIG. 9 of the intermediate product of FIG. 10 after the completion of the local interconnects. It can be seen from FIG. 11 that the electric conductors bridge every second shallow trench isolation in the level of the metal layer 20 above the dielectric grating 17. The metal layer 20 can instead be structured in such a manner that each source/drain region is contacted individually. In further process steps, a covering dielectric layer or passivation is applied, in which the bit lines are structured.

Although the present invention and its advantages have been described in detail, it should be understood that various changes, substitutions and alterations can be made herein without departing from the spirit and scope of the invention as defined by the appended claims.

What is claimed is:

1. A method for producing a semiconductor memory device, the method comprising:
providing a semiconductor body having a main surface with shallow trench isolations running parallel at a distance from one another;
forming word line stacks running parallel at a distance from one another transversely to said shallow trench isolations and having sidewalls and gaps between them;
forming source/drain regions in said semiconductor body adjacent to the word line stacks;
applying a lateral word line insulation on said sidewalls of said word line stacks;
filling a dielectric material into said gaps between said word line stacks;
removing said dielectric material in regions between said word line stacks and between said shallow trench isolations down to said main surface of said semiconductor body in areas of said source/drain regions, leaving residual parts of said dielectric material to form dielectric gratings between said word line stacks;
forming spacers of dielectric material on sidewalls of said word line stacks and said dielectric gratings, leaving areas of said main surface above said source/drain regions free;
epitaxially growing a semiconductor layer on said main surface between said spacers; and
applying contacts provided for bit lines on said semiconductor layer.

2. The method according to claim 1, wherein forming word line stacks comprises:
forming a gate dielectric on said main surface;
applying at least one electrically conductive word line layer on said gate dielectric;
applying at least one electrically insulating material on said at least one word line layer; and
structuring said electrically insulating material and said at least one word line layer to form said word line stacks.

3. The method according to claim 1, wherein forming source/drain regions comprises implanting dopant atoms in a self-aligned manner with said word line stacks.

4. The method according to claim 1, wherein removing said dielectric material comprises:
applying a mask over said dielectric material, said mask having windows between striplike parts running above said shallow trench isolations; and
using said mask to remove said dielectric material in said regions between said word line stacks and between said shallow trench isolations down to said main surface of said semiconductor body in areas of said source/drain regions, leaving residual parts of said dielectric material to form dielectric gratings between said word line stacks.

5. The method according to claim 1, wherein said semiconductor body comprises a silicon body.

6. The method according to claim 5, wherein the semiconductor layer comprises a silicon layer.

7. The method according to claim 6, further comprising forming a silicide layer on said semiconductor layer.

8. The method according to claim 7, further comprising:
applying a metal layer on said silicide layer;
structuring said metal layer to form local interconnects; and
applying bit lines running transversely to said word line stacks and being connected to said local interconnects.

9. The method according to claim 5, wherein said spacers are formed of silicon nitride.

10. The method according to claim 1, wherein filling a dielectric material into said gaps between said word line stacks comprises using boron phosphorus silicate glass (BPSG) to fill into the gaps between the word line stacks.

11. A method for producing a semiconductor memory device that includes bitline contacts and source/drain regions, the method comprising:
providing a semiconductor body having a main surface with shallow trench isolations running parallel at a distance from one another;
forming a gate dielectric that includes a memory layer on said main surface;
applying at least one electrically conductive word line layer on said gate dielectric;
applying at least one electrically insulating material on said at least one word line layer;
structuring said electrically insulating material and said at least one word line layer to form word line stacks running parallel at a distance from one another transversely to said shallow trench isolations and having sidewalls and gaps between them;
implanting dopant atoms in a self-aligned manner with said word line stacks to form source/drain regions in said semiconductor body;
applying a lateral word line insulation on said sidewalls of said word line stacks;
filling a dielectric material into said gaps between said word line stacks;
applying a mask over said dielectric material, said mask having windows between striplike parts running above said shallow trench isolations;
using said mask to remove said dielectric material in regions between said word line stacks and between said shallow trench isolations down to said main surface of said semiconductor body in areas of said source/drain regions, leaving residual parts of said dielectric material to form dielectric gratings between said word line stacks;
forming spacers of dielectric material on sidewalls of said word line stacks and said dielectric gratings, leaving areas of said main surface above said source/drain regions free;
epitaxially growing a semiconductor layer on said main surface between said spacers; and
applying contacts provided for bit lines on said semiconductor layer.

12. The method according to claim 11, further comprising forming a silicide layer on said semiconductor layer.

13. The method according to claim 12, further comprising:
applying a metal layer on said silicide layer;
structuring said metal layer to form local interconnects; and
applying bit lines running transversely to said word line stacks and being connected to said local interconnects.

14. The method according to claim 13, wherein:
said local interconnects are arranged in such a fashion that in a first quadruple of memory cells comprising a first memory cell, a second memory cell that is adjacent to the first memory cell in a direction of the word lines, and a third memory cell and a fourth memory cell that are adjacent to the first and second memory cells, respectively, in a direction of the bit lines, and further comprising a first source/drain region of the first memory cell, a first source/drain region of the second memory cell, a first source/drain region of the third memory cell, and a first source/drain region of the fourth memory cell;
the first source/drain regions are electrically connected by a first one of the local interconnects;
the memory cells of the first quadruple forming first memory cells of a second, third, fourth, and fifth quadruple of memory cells arranged like the first quadruple; and
a second source/drain region of each of the memory cells of the first quadruple is electrically connected to first source/drain regions of a second, third, and fourth memory cell of the respective second, third, fourth or fifth quadruple of memory cells by a second, third, fourth, and fifth one, respectively, of the local interconnects.

15. The method according to claim 11, wherein filling a dielectric material into said gaps between said word line stacks comprises using boron phosphorus silicate glass (BPSG) to fill into the gaps between the word line stacks.

16. The method according to claim 11, wherein said spacers are formed so that the area of said main surface located above said source/drain regions is left free and the shallow trench isolations are completely covered by said word line stacks, said spacers, and said dielectric gratings.

17. The method according to claim 11, wherein said spacers are formed of silicon nitride.

18. The method according to claim 11, wherein the semiconductor body comprises a silicon substrate.

19. The method according to claim 18, wherein epitaxially growing a semiconductor layer comprises epitaxially growing a silicon layer.
